(19) United States
(12) Patent Application Publication
(10) Pub. No.: US 2022/0319307 A1
(43) Pub. Date: Oct. 6, 2022

(54) TRAFFIC CONTROL SYSTEM, TRAFFIC CONTROL METHOD, AND STORAGE MEDIUM

(71) Applicant: TOYOTA JIDOSHA KABUSHIKI KAISHA, Toyota-shi (JP)

(72) Inventors: Atsushi KAWAMOTO, Nagakute-shi (JP); Yasuhiro IKUTA, Nagoya-shi (JP)

(73) Assignee: TOYOTA JIDOSHA KABUSHIKI KAISHA, Toyota-shi (JP)

(21) Appl. No.: 17/591,805

(22) Filed: Feb. 3, 2022

(30) Foreign Application Priority Data
Mar. 31, 2021 (JP) 2021-061467

(51) Int. Cl. G08G 1/01; G08G 1/0967; G08G 1/16; G06F 17/11

(52) U.S. Cl. CPC G08G 1/0129; G08G 1/0145; G08G 1/096725; G08G 1/164; G08G 1/166; G06F 17/11

(57) ABSTRACT

A traffic control system includes: an acquisition unit that acquires a traffic pattern indicating a predetermined virtual vehicle flow corresponding to a current traffic demand; and an allocation unit that allocates a real vehicle to a virtual vehicle in the acquired traffic pattern. The traffic control system may further include an estimation unit that estimates the current traffic demand based on a time slot or current traffic information.

### CROSS-REFERENCE TO RELATED APPLICATION

This application claims priority to Japanese Patent Application No. 2021-061467 filed on Mar. 31, 2021, incorporated herein by reference in its entirety.

### BACKGROUND

1. Technical Field

The present disclosure relates to a traffic control system, a traffic control method, and a storage medium.

2. Description of Related Art

WO 2017/065182 discloses a vehicle control system configured by a vehicle control device mounted on a vehicle and a server connected to the vehicle control device by a network.

### SUMMARY

In WO 2017/065182, in order to realize autonomous driving of a vehicle, the vehicle needs to execute a number of complicated processes such as identification of the position of the own vehicle, identification of the position of another vehicle, and calculation of the traveling route. In addition, the server needs to collect travel trajectories from a plurality of vehicles and constantly update the collected data. In a vehicle control system in which the vehicle and the server need to execute complicated processing, a collision accident may occur once an error occurs.

The present disclosure has been made to solve such an issue, and an object of the present disclosure is to provide a traffic control system, a traffic control method, and a storage medium for realizing simpler and safer autonomous driving.

A traffic control system according to a first aspect of the present disclosure includes: an acquisition unit that acquires a traffic pattern indicating a predetermined virtual vehicle flow corresponding to a current traffic demand; and an allocation unit that allocates a real vehicle to a virtual vehicle in the acquired traffic pattern.

A traffic control method according to a second aspect of the present disclosure includes: a step of acquiring a traffic pattern indicating a predetermined virtual vehicle flow corresponding to a current traffic demand; and a step of allocating a real vehicle to a virtual vehicle in the acquired traffic pattern.

A storage medium according to a third aspect of the present disclosure stores a program. The program causes a computer to perform operations including: a process of acquiring a traffic pattern indicating a predetermined virtual vehicle flow corresponding to a current traffic demand; and a process of allocating a real vehicle to a virtual vehicle in the acquired traffic pattern.

According to the present disclosure, it is possible to provide a traffic control system, a traffic control method, and a storage medium for realizing simpler and safer autonomous driving.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a virtual vehicle flow (traffic pattern) derived by simulation according to a first embodiment;

FIG. 2 is a diagram illustrating an allocation of a real vehicle to a virtual vehicle in a traffic pattern according to the first embodiment;

FIG. 3 is a schematic view showing a configuration of a traffic control system according to the first embodiment;

FIG. 4 is a flowchart showing a traffic control method according to the first embodiment;

FIG. 5 is a flowchart showing a flow of generation of the traffic pattern according to a second embodiment;

FIG. 6 is a diagram illustrating an example of the traffic pattern according to the second embodiment;

FIG. 7 is a diagram illustrating an example of the traffic pattern according to the second embodiment;

FIG. 8 is a diagram illustrating a modification of the traffic pattern according to the second embodiment;

FIG. 9 is a diagram illustrating a modification of the traffic pattern according to the second embodiment;

FIG. 10 is a block diagram showing a configuration of the server according to the second embodiment;

FIG. 11 is a flowchart illustrating an allocation method of allocating the real vehicle to the virtual vehicle in the traffic pattern according to the second embodiment;

FIG. 12 is a diagram illustrating the allocation method of allocating the real vehicle to the virtual vehicle in the traffic pattern according to the second embodiment; and

FIG. 13 is a diagram illustrating the allocation method of allocating the real vehicle to the virtual vehicle in the traffic pattern according to the second embodiment.

### DETAILED DESCRIPTION OF EMBODIMENTS

### First Embodiment

Hereinafter, embodiments of the present disclosure will be described below with reference to the drawings.

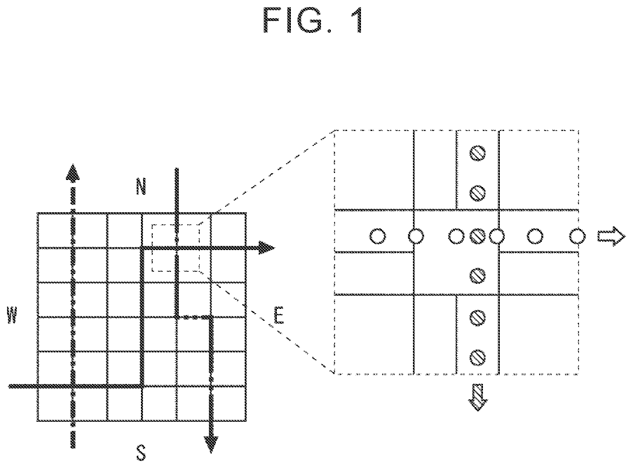

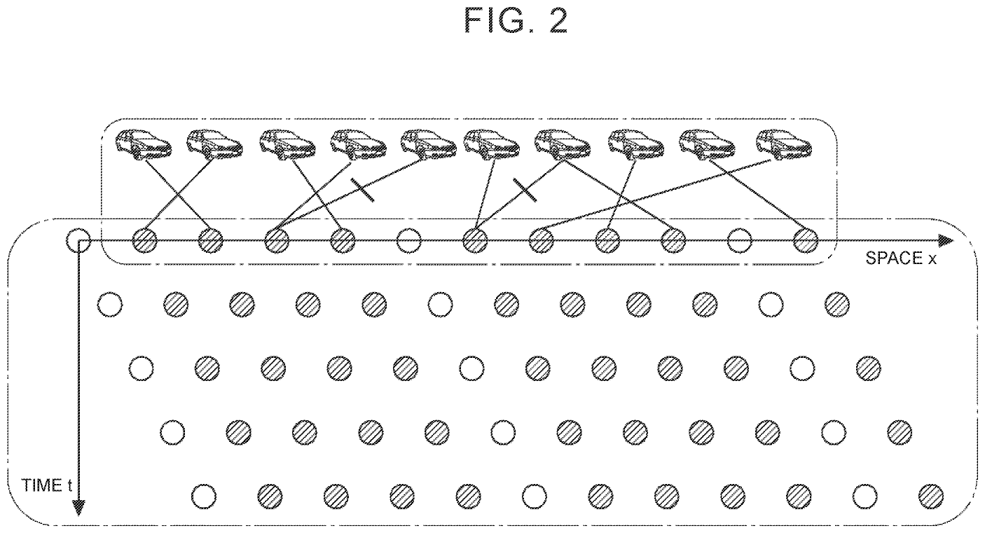

First, the outline of a first embodiment of the present disclosure will be described with reference to FIGS. 1 and 2.

The present disclosure generally relates to an autonomous driving system, and more specifically to a traffic control system that realizes autonomous driving of a vehicle in response to traffic demand. FIG. 1 is a diagram illustrating a virtual vehicle flow derived by simulation. The traffic demand refers to the number of vehicles trying to pass through a road at each time slot. The traffic demand generally varies by time of day and region. Therefore, the virtual vehicle flow (also referred to as a traffic pattern) corresponding to the traffic demand for each time slot or region is created in advance. An ideal virtual vehicle flow that ensures that vehicles related to autonomous driving do not collide with each other, that is, virtual vehicles do not enter a particular area (for example, an intersection) at the same time can be derived by simulation. For example, a known traffic simulator can be used to derive an ideal virtual vehicle flow (traffic pattern) corresponding to various traffic demands. The traffic patterns for various time slots in a specific area may be derived in advance. As shown on the right side in FIG. 1, the traffic pattern is a smooth flow in which a plurality of the virtual vehicles move over time so as to satisfy the current traffic demand, and determined such that the virtual vehicles do not collide with each other at an intersection or the like.

Next, as shown in FIG. 2, the real vehicle is dynamically allocated to the ideal virtual vehicle flow obtained as described above. That is, a computer or artificial intelligence selects a stored traffic pattern corresponding to the current traffic demand and solves an allocation problem of allocating the real vehicle to the virtual vehicle in the traffic pattern. In the traffic control system, the position information of each autonomous vehicle can be identified by a known positioning system such as a global positioning system (GPS) or a beacon positioning system. Further, a radar and a surveillance camera for monitoring the surrounding environment may be installed on the road. In addition, the traffic control system stores maps of various areas and map information indicating position information indicating roads (including general roads and expressways), intersections, facilities, stores, etc. in a storage unit. The traffic control system can perform vehicle allocation to a predetermined traffic pattern corresponding to the traffic demand while identifying the position information of each autonomous driving vehicle in real time.

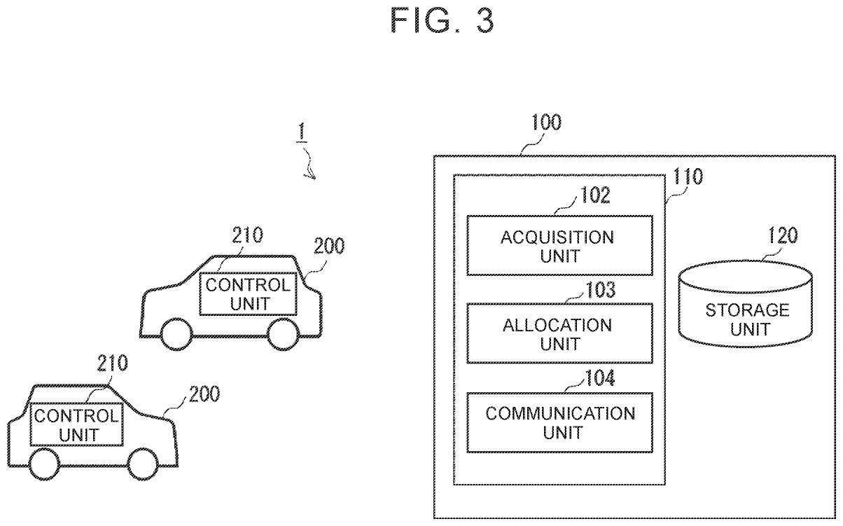

FIG. 3 is a schematic view showing the configuration of a traffic control system.

The traffic control system 1 includes a traffic control device (also referred to as a server 100) and a plurality of vehicles 200 communicatively connected via a network (including a wired and wireless network). The server 100 realizes autonomous driving by remotely operating the vehicles 200 via the network (including wired and wireless networks).

The server 100 is realized by a computer including a control unit 110 and a storage unit 120. The control unit 110 is composed of a processor and may include an acquisition unit 102, an allocation unit 103, and a communication unit 104. The control unit 110 may be configured by circuits such as electrical components (for example, one or more integrated circuits such as microprocessors, microcontrollers, application-specific integrated circuits, digital signal processors, and central processing units (CPUs)).

The server 100 can be implemented in one or more stand-alone data processing devices or in a distributed network of computers.

The acquisition unit 102 acquires a traffic pattern indicating a predetermined flow of virtual vehicles corresponding to the current traffic demand. The allocation unit 103 allocates the real vehicle to the virtual vehicle in the acquired traffic pattern.

The allocation unit 103 can dynamically allocate the real vehicle to the virtual vehicle in the traffic pattern by solving an allocation problem using a specific equation or artificial intelligence (for example, a deep neural network model) that will be described later.

The communication unit 104 is a communication interface with the network. The communication unit 104 is used to communicate with other network node devices constituting the traffic control system. The communication unit 104 may be used to perform wireless communication. For example, the communication unit 104 may be used to perform wireless local area network (LAN) communication specified in the IEEE802.11 series or mobile communication specified in the third generation partnership project (3GPP) or the like. The server 100 can continuously acquire the position information of each vehicle from a large number of vehicles 200 via the communication unit 104 and identify the traveling trajectory of each vehicle.

The vehicle 200 also includes a communication unit (not shown) that communicates with the server and a control unit 210 that controls the vehicle based on an instruction from the server. The vehicles 200 each include a position information receiving unit such as a GPS receiver. The control unit 210 can operate an actuator of the vehicle in accordance with the traffic pattern instructed by the server based on various sensors (e.g., vehicle speed sensor and steering angle sensor) mounted on the vehicle and the position information of the vehicle. The actuator can control, for example, a steering, an accelerator, a brake and the like. Further, the vehicle 200 includes the position information receiving unit (not shown), and can transmit the position information of each vehicle to the server 100 together with the vehicle identification number via the communication unit.

According to some embodiments, in the traffic control system, some or all of the functions of the server 100 may be provided in a computer mounted on the vehicle.

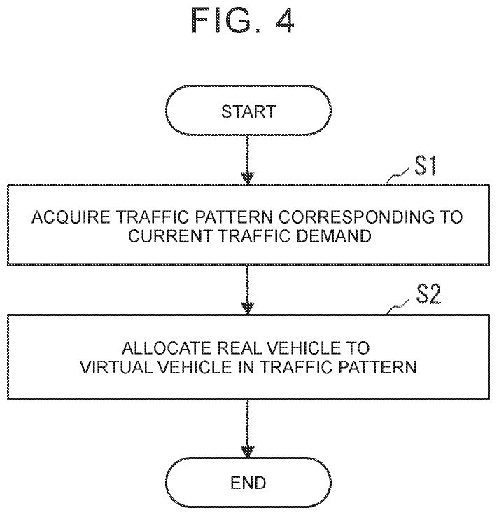

FIG. 4 describes a traffic control method according to the present embodiment.

A traffic pattern indicating a predetermined virtual vehicle flow corresponding to the current traffic demand is acquired (step S1). The real vehicle is allocated to the virtual vehicle in the acquired traffic pattern (step S2).

As described above, the traffic control system in the present embodiment can realize safe autonomous driving while a delay is suppressed by dynamically allocating the real vehicle based on the traffic pattern prepared in advance.

In another embodiment, the server 100 may include an estimation unit that estimates the current traffic demand based on the time slot or traffic information. The traffic information may include traffic congestion information on expressways and general roads, and may include traffic big data such as various sensor information from sensors installed on vehicles and roads, and position information from a navigation system.

In another embodiment, the storage unit 120 may be provided to store a plurality of traffic patterns for a plurality of traffic demands obtained by simulation. The traffic patterns corresponding to the traffic demands can include, for example, at least one of a plurality of traffic patterns corresponding to a plurality of different time slots, a plurality of different weather conditions, and a plurality of different emergencies. In another embodiment, when an accident occurs in a specific area (for example, at a specific intersection), a traffic pattern that bypasses the intersection can be prepared. The storage unit 120 may be provided in the server or may be connected to the server via a network.

### Second Embodiment

Next, traffic control system and method according to a second embodiment will be described.

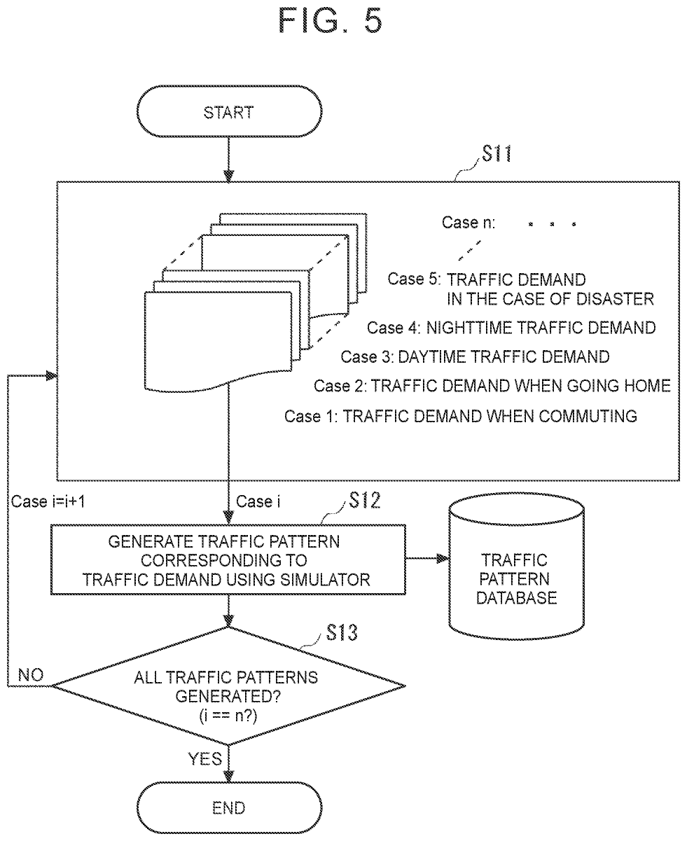

First, generation of a simulation for an ideal virtual vehicle flow will be specifically described with reference to the flowchart in FIG. 5. FIG. 5 is a flowchart showing a flow of generation of the traffic pattern.

Various traffic demands are assumed (step S11). Examples of the traffic demand include, but are not limited to, the traffic demands when commuting, when going home, for daytime, for nighttime, and in the case of disasters. For example, the traffic demands for different time slots, different weather conditions (e.g., sunny, rainy, and snowfall) or the traffic demands that cope with different emergencies (e.g., disasters, earthquakes, floods, typhoons, accidents, and construction) can be assumed.

Next, the traffic pattern corresponding to one of the various assumed traffic demands is generated using a simulator (step S12). A known traffic simulator can be used as the simulator. The generated traffic pattern is stored in a server that remotely controls autonomous driving or in a database connected to the server via the network. The database is an example of the storage unit 120.

When the traffic patterns corresponding to all the assumed traffic demands are generated (YES in step S13), this process ends. On the other hand, when the traffic patterns corresponding to all the assumed traffic demands are not generated (NO in step S13), the processes in steps S11 and S12 are repeated until the traffic patterns corresponding to all the traffic demands are generated.

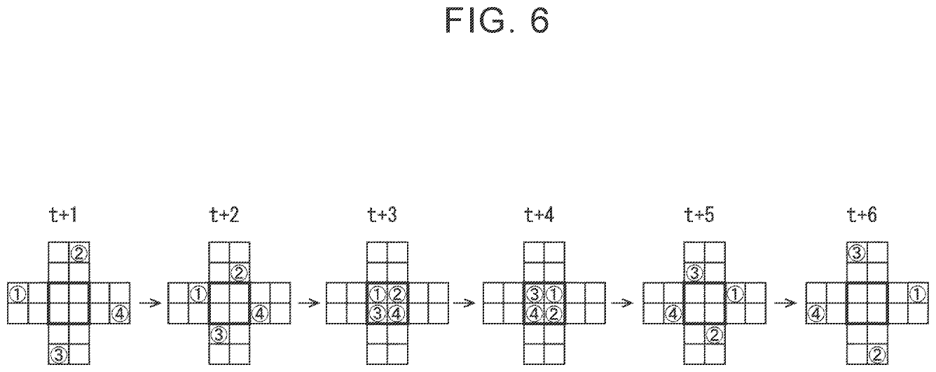

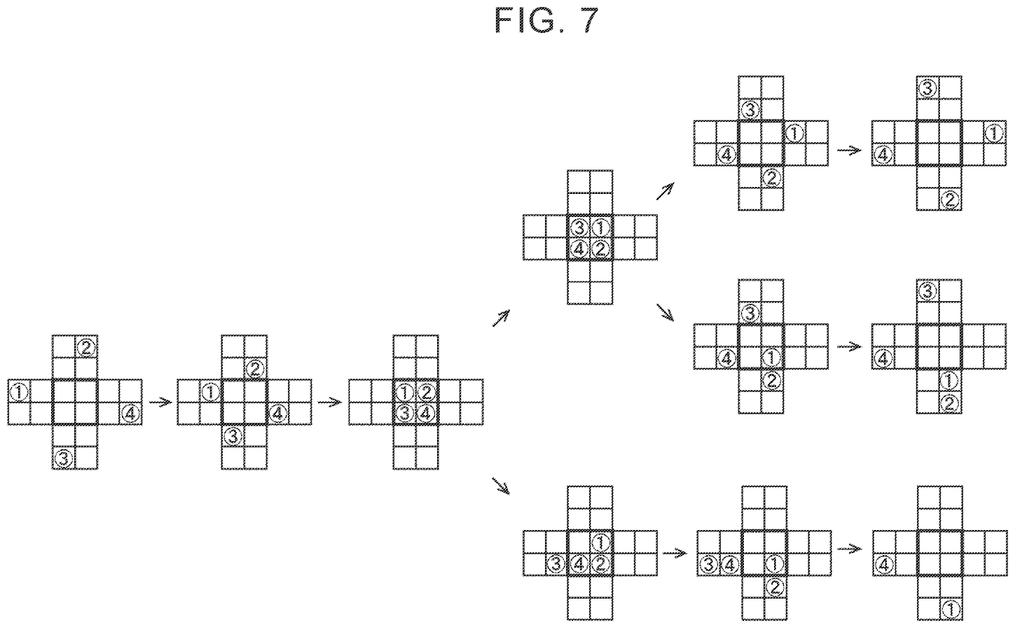

Here, an example of an ideal traffic pattern will be described with reference to FIGS. 6 and 7.

In the embodiment of the present disclosure, it is assumed that all virtual vehicles in a specific area are caused to travel by autonomous driving. In this example, it is assumed that all four virtual vehicles are remotely and automatically controlled by the present system. In FIG. 6, the road is divided into a plurality of virtual blocks having the same size and shape for convenience. In the example of FIG. 6, at t+1, each of the four virtual vehicles travels toward the intersection at a predetermined speed. In the diagram at t+3, each of the four virtual vehicles enters the intersection. Next, in the diagram at t+4, each virtual vehicle advances to the next block without slowing down and colliding with each other. In the example of FIG. 6, it is assumed that all virtual vehicles travel straight. However, the ideal traffic pattern is not limited to this.

For example, as shown in FIG. 7, the ideal traffic pattern can be generated even when one or more vehicles entering the intersection subsequently turn right or left. In this example, four virtual vehicles are shown. However, an appropriate number of virtual vehicles can be prepared in accordance with the traffic demand. Further, the road can be arbitrarily set by combining roads having various shapes, such as general roads, expressways, crossroads, T-junctions, straight lanes, and curves, and traffic restrictions. In another embodiment, it is possible to prepare a traffic pattern that bypasses a specific area (e.g., a specific intersection) when an accident occurs in the specific area (e.g., the intersection).

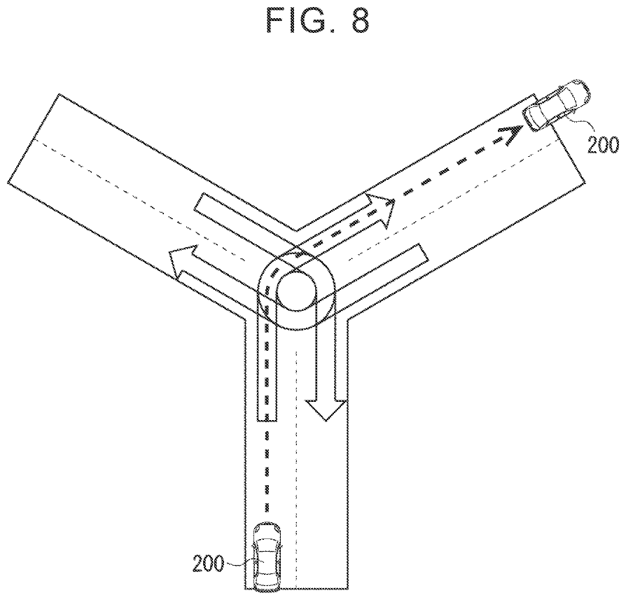

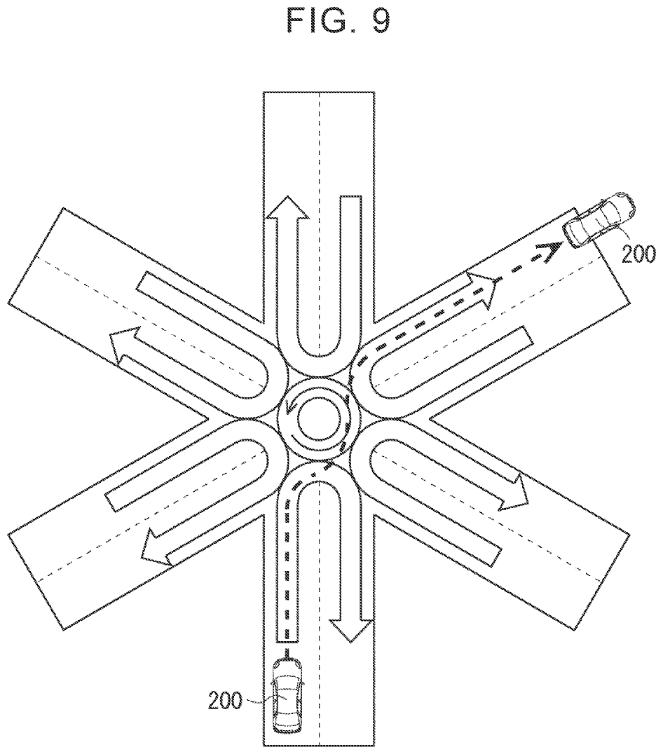

FIGS. 8 and 9 are diagrams for explaining modifications of the traffic patterns. FIG. 8 shows an example of a three-way junction including a roundabout. FIG. 9 shows an example of a six-forked road including a roundabout. The ideal flow can be calculated in any layout in which the vehicle passes through the intersection without contacting with other vehicles, without depressing a brake pedal, or without waiting for other vehicles to pass, and in a traveling direction determined for each vehicle.

As described above, it is possible to generate the ideal traffic pattern that maximizes the traveling speed as much as possible such that the vehicles do not collide with each other. As described above, the ideal traffic pattern is stored in advance in the database in the traffic control system.

In the above example, it is assumed that a person simulates the ideal traffic pattern. However, such a simulation requires an enormous amount of time. Therefore, artificial intelligence may be used to create the ideal traffic pattern in advance when necessary.

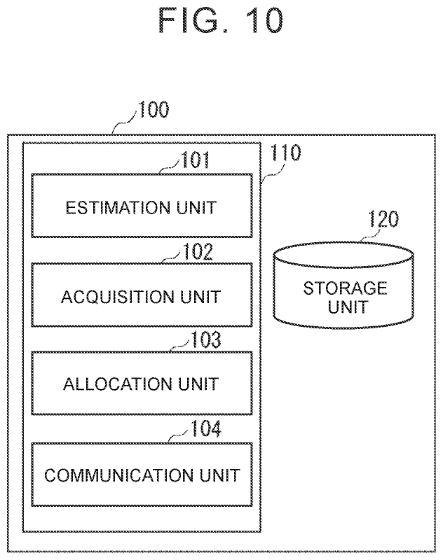

FIG. 10 is a block diagram showing a configuration of the server according to the second embodiment. The server 100 is realized by a computer including the control unit 110 and the storage unit 120. The control unit 110 is composed of a processor and may include an estimation unit 101, the acquisition unit 102, the allocation unit 103, and the communication unit 104. In the present embodiment, the estimation unit 101 different from that of the first embodiment is added. The estimation unit 101 estimates the current traffic demand based on the time slot or traffic information. The estimation unit 101 can also estimate the current traffic demand by collecting vehicle positions from respective vehicles in a specific area and using the position information collected from a large number of vehicles. In addition, the estimation unit 101 can estimate the current traffic demand using the traffic information on accidents and traffic jams and the traffic big data.

The acquisition unit 102 acquires a traffic pattern indicating a predetermined virtual vehicle flow corresponding to the current traffic demand estimated by the estimation unit 101. The allocation unit 103 allocates the real vehicle to the virtual vehicle in the acquired traffic pattern. The communication unit 104 is a communication interface with the network. The communication unit 104 is used to communicate with other network node devices constituting the traffic control system. The communication unit 104 may be used to perform wireless communication. For example, the communication unit 104 may be used to perform wireless LAN communication specified in the IEEE802.11 series or mobile communication specified in the 3GPP or the like.

Further, in the present system, when a radar and a surveillance camera for monitoring the surrounding environment are installed on the road, the server 100 can identify that an accident has occurred by acquiring the surrounding environment information from the radar and the surveillance camera via the network. That is, when the estimation unit 101 estimates or identifies that an accident has occurred in a specific area (for example, a specific intersection), the acquisition unit 102 may acquire a traffic pattern that bypasses the specific area (for example, the intersection).

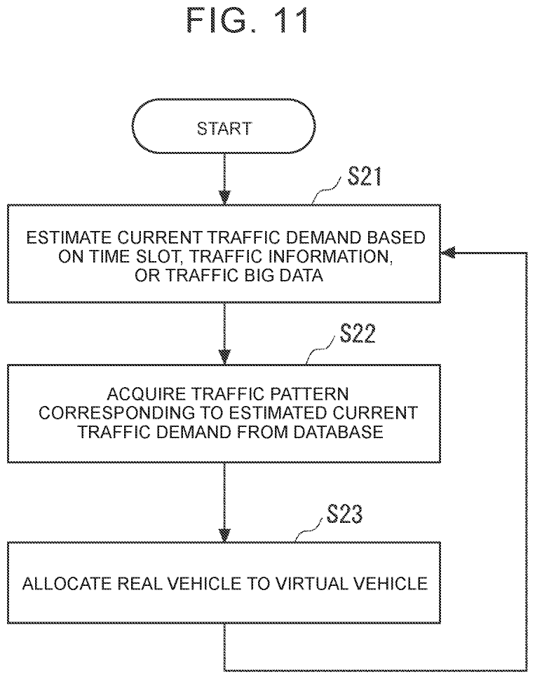

Next, a method of allocating the real vehicle to the virtual vehicle in the above traffic pattern will be described with reference to the flowchart in FIG. 11.

The estimation unit 101 of the control unit of the server that controls the autonomous driving estimates the current traffic demand based on the time slot, the traffic information, or the traffic big data (step S21).

The acquisition unit 102 acquires the traffic pattern corresponding to the estimated current traffic demand from the database (step S22). The optimal traffic pattern is selected and the virtual vehicle flow is generated.

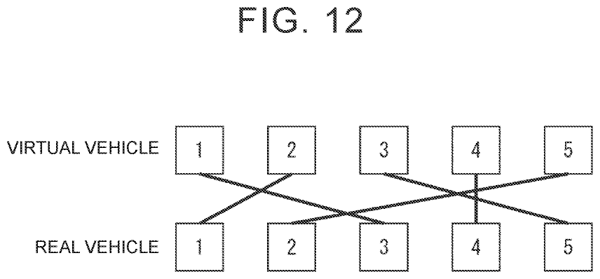

The allocation unit 103 allocates the real vehicle to the virtual vehicle (step S23). It is possible to derive the correspondence by formulating the correspondence between the virtual vehicles in the traffic pattern corresponding to the current traffic demand and the real vehicles (FIG. 12) as an allocation problem and solving the allocation problem. In addition, artificial intelligence such as a neural network can be used to dynamically solve the allocation problem above. The neural network can include a deep neural network (DNN), a convolutional neural network (CNN), a recurrent neural network (RNN), and the like. However, when the neural network is used to dynamically solve the allocation problem, the allocation problem cannot be continuously solved and the system may stop in the middle.

Therefore, in this example, a selection equation can be applied to dynamically solve the allocation problem. For more information, see “Treatment of combinatorial optimization problems using selection equations with cost terms” by H. Haken, PHYSICAD 1999.

FIG. 12 shows an allocation method between the virtual vehicles and the real vehicles. The real vehicles in number n (n is a natural number) are allocated to the virtual vehicles in number n (FIG. 12 shows an example of n=5). Only one real vehicle is allocated to each virtual vehicle. The allocation problem is solved such that the total cost, that is, the sum of allocations, is minimized. This problem can be generalized for higher dimensional allocations.

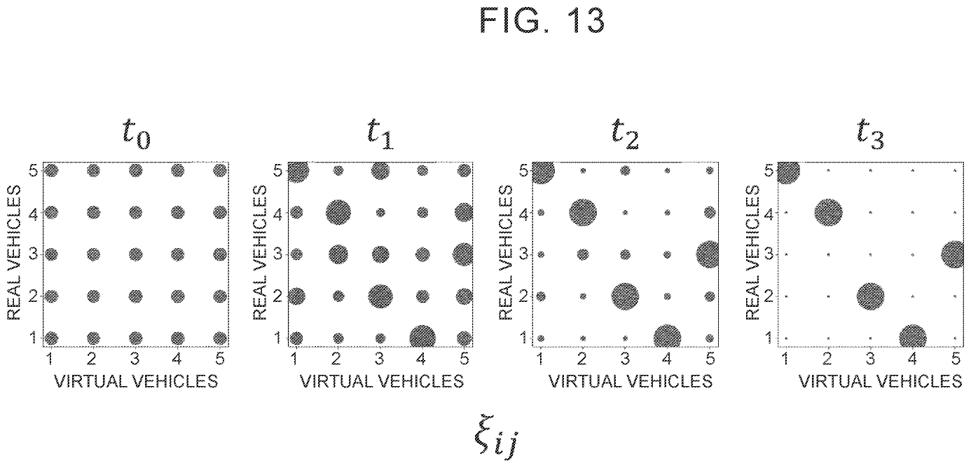

FIG. 13 shows four time steps of simulating a combined selection equation to solve a two-dimensional allocation problem with a problem size of five by five (5×5). The dots are arranged as a matrix (ξᵢⱼ). The dot size is proportional to the value ξᵢⱼ. Time t₀ indicates the initial state. At time t₃, a stable point corresponding to the permutation matrix appears.

As explained in detail in the paper, the following equation of motion can be obtained.

$${\dot{ξ}}_{ij} = ( 1 - α {c}_{ij} ) {ξ}_{ij} - {ξ}_{ij}^{3} - β {ξ}_{ij} ( {\sum }_{{j}^{′} \neq j} {ξ}_{{ij}^{′}}^{2} + {\sum }_{{i}^{′} \neq i} {ξ}_{{i}^{′} j}^{2} ) \qquad Equation 1$$

The equation can be applied to the allocation problem according to the present embodiment by setting i and j as the virtual vehicle and the real vehicle. With this, the issue that solution of the problem stops due to use of the neural network can be suppressed, and the allocation problem can be solved stably.

The traffic control system causes each allocated vehicle to autonomously travel in accordance with the traffic pattern. All vehicles are not steered by the drivers of the vehicles and can travel autonomously based on instructions from the traffic control system. Further, in another embodiment, a front camera mounted on the vehicle may capture an image of a preceding vehicle to maintain the inter-vehicle distance from the preceding vehicle. With this configuration, in the traffic control system, each vehicle can be moved while maintaining the position of the corresponding virtual vehicle in the traffic pattern based on the captured images.

In the traffic control system described above, it is possible to estimate the current traffic demand using the traffic information and the traffic big data, and acquire a preset traffic pattern that matches the estimated traffic demand. Furthermore, by allocating real vehicles using the traffic pattern that matches the traffic demand, it is possible to suppress the occurrence of traffic congestion and the like.

Note that, the present disclosure is not limited to the above embodiments, and can be appropriately modified without departing from the spirit. The present system is based on assumption that all vehicles in a specific area travel by autonomous driving. However, the present disclosure is not limited to this. For example, in a specific area, all vehicles at a specific time (for example, in the event of an emergency) may be caused to travel by autonomous driving. That is, in normal times, when the road is not congested, vehicles that are not autonomously driven may travel. In the event of an emergency, when the road is congested, all vehicles may be caused to travel by autonomous driving. That is, the present system may be used only in the event of an emergency.

Note that, the program described above can be stored using various types of non-transitory computer-readable media and supplied to a computer. The non-transitory computer-readable media include various types of tangible storage media. Examples of the non-transitory computer-readable media include magnetic storage media (e.g. flexible disks, magnetic tapes, hard disk drives), magneto-optical storage media (e.g. magneto-optical disks), compact disc read-only memory (CD-ROM), compact disc recordable (CD-R), compact disc rewritable (CD-R/W), and semiconductor memory (e.g. mask ROM, programmable ROM (PROM), erasable PROM (EPROM), flash ROM, random access memory (RAM)). The program may also be supplied to the computer by various types of transitory computer-readable media. Examples of the transitory computer-readable media include electrical signals, optical signals, and electromagnetic waves. The transitory computer-readable media can supply the program to the computer via a wired communication path such as an electric wire and an optical fiber, or a wireless communication path.

What is claimed is:

1. A traffic control system comprising:
an acquisition unit that acquires a traffic pattern indicating a predetermined virtual vehicle flow corresponding to a current traffic demand; and
an allocation unit that allocates a real vehicle to a virtual vehicle in the acquired traffic pattern.

2. The traffic control system according to claim 1, further comprising an estimation unit that estimates the current traffic demand based on a time slot or current traffic information.

3. The traffic control system according to claim 1, further comprising a storage unit that stores a plurality of the traffic patterns corresponding to a plurality of the traffic demands.

4. The traffic control system according to claim 3, wherein the traffic patterns corresponding to the traffic demands are traffic patterns corresponding to at least one of a plurality of different time slots, a plurality of different weather conditions, and a plurality of different emergencies.

5. The traffic control system according to claim 3, wherein the traffic patterns corresponding to the traffic demands include a traffic pattern that bypasses a specific area when an accident occurs in the specific area.

6. The traffic control system according to claim 1, further comprising a control unit that communicates with the allocated real vehicle and controls traveling of the real vehicle so as to be consistent with traveling of the virtual vehicle in the traffic pattern.

7. The traffic control system according to claim 1, wherein the allocation unit allocates the real vehicle to the virtual vehicle based on an equation below.
$${\dot{ξ}}_{ij} = ( 1 - α {c}_{ij} ) {ξ}_{ij} - {ξ}_{ij}^{3} - β {ξ}_{ij} ( {\sum }_{{j}^{′} \neq j} {ξ}_{{ij}^{′}}^{2} + {\sum }_{{i}^{′} \neq i} {ξ}_{{i}^{′} j}^{2} ) \qquad Equation 1$$

8. A traffic control method comprising:
a step of acquiring a traffic pattern indicating a predetermined virtual vehicle flow corresponding to a current traffic demand; and
a step of allocating a real vehicle to a virtual vehicle in the acquired traffic pattern.

9. A non-transitory storage medium storing a program that causes a computer to perform operations comprising:
a process of acquiring a traffic pattern indicating a predetermined virtual vehicle flow corresponding to a current traffic demand; and
a process of allocating a real vehicle to a virtual vehicle in the acquired traffic pattern.
